(19) United States
(12) Patent Application Publication
(10) Pub. No.: US 2014/0061188 A1
(43) Pub. Date: Mar. 6, 2014

(54) LIGHTING ASSEMBLY FOR MICROWAVE OVEN ILLUMINATION AND MICROWAVE OVEN EQUIPPED WITH THE SAME

(71) Applicants: Gang Liu, Santa Clara, CA (US); Tong Wang, Anshan (CN)

(72) Inventors: Gang Liu, Santa Clara, CA (US); Tong Wang, Anshan (CN)

(21) Appl. No.: 13/597,195

(22) Filed: Aug. 28, 2012

(51) Int. Cl. H05B 33/02; H05K 13/00; H05B 6/64

(52) U.S. Cl. 219/679; 313/110; 29/592.1

(57) ABSTRACT

This invention relates to a microwave oven lighting assembly. The lighting assembly has a LED lamp and one or more light-guiding members to collect and to condense the light of the lamp; the lighting assembly is placed outside of the microwave oven cavity, casting the light into the cavity through holes on the cavity wall. The invention requires significantly less energy consumption and provides greatly enhanced oven cavity illumination.

### CROSS-REFERENCE TO RELATED APPLICATIONS

None.

### FIELD OF THE INVENTION

The present invention relates, in general, to a lighting assembly and a method for improving lighting of microwave ovens. More particularly, the present invention relates to improved lighting assemblies and the placement of said sources in microwave cavities for increased lighting intensity and improved viewing of the oven contents during cooking

### BACKGROUND OF THE INVENTION

Today, microwave ovens are a common household item found in nearly every home of the industrialized world and have become indispensible to our modern life. These household appliances have become popular because of their convenience and relative small sizes. Typically, a microwave oven comprises a cooking chamber (or oven cavity) for receiving food to be cooked and a door with a viewing window for monitoring the food during the cooking process.

To monitor the food during cooking, the cooking chamber must be adequately illuminated. Prior art microwave ovens typically uses a tungsten filament appliance light bulb which provides poor illumination. In order for people to protect the filament from the microwave some structures such as an iron screen have to be installed between the bulb and the food chamber (or the microwave oven cavity), thus deteriorating the already poor viewing conditions. It is also impractical and expensive to simply adopt high power bulbs in conventional microwave ovens for daily use.

U.S. Pat. No. 5,712,468 teaches an illuminating system that uses microwave-resistant quartz halogen lamps located in the food chamber. Halogen lamps must operate at higher temperatures, which makes their quartz envelope vulnerable to oils and other contaminants. Moreover, in order to achieve adequate lighting, the power required to drive the halogen lamp and the associated transformer are substantial, which reduces the amount of power available for cooking

The known microwave oven illumination devices are not capable of providing sufficient light because of protective yet intrusive structures for the light bulbs while still suffering from low lighting efficiency. These problems have remained unsolved. Therefore, there still exists a need for an improved microwave illuminating system that is energy efficient and capable of providing adequate lighting to the cooking chamber (or the microwave oven cavity).

### SUMMARY OF THE INVENTION

The inventors of the present invention have recognized that what is needed in order to solve the above mentioned problem is to provide a differential high-illumination low energy-consumption light source and deliver the light from the light source efficiently into the microwave oven cavity.

Accordingly, one aspect of the present invention is directed to a lighting assembly capable of efficiently collecting light from a light source and projecting the light to illuminate a designated surface area or volume of space in a microwave oven. Embodiments of lighting assemblies in accordance with this aspect of the present invention will generally include a lamp for generating light; and a lamp-front assembly comprising one or more light-guiding member(s) integrated for collecting, condensing, and distributing light generated by the lamp. In some preferred embodiments, the lamp-front assembly will have a light-receiving end, a light-exiting end, and a bulging section connecting the light-receiving end and the light-exiting-end. The lamp is embedded in the light-receiving-end of the lamp-front assembly, The portion of the lamp-front assembly from the light-receiving end to the bulging section is configured to collect light generated from the lamp, whereas the portion from the bulging section to the light-exiting end has a tapered shape to condense and distribute light to the designated surface area or volume of space.

In a preferred embodiment, the lamp is a light emitting diode (LED). In other preferred embodiments, the light-guiding member(s) are single-piece lenses. In still some preferred embodiments, at least one of the single-piece lenses is a total internal reflection (TIR) lens.

In some preferred embodiments, the light-exiting end of the lamp-front assembly has a concaved shape. In some other embodiments, the lamp-front assembly comprises a first lens forming the portion of the lamp-front assembly from the light-receiving end to the bulging section for light collection, and a second lens forming the portion of the lamp-front assembly from the bulging section to the light-exiting end, the second lens having a tapered shape for light condensing and distributing. The lenses are seamlessly connected to each other at the bulging section.

Another aspect of the present invention is directed to a microwave oven equipped with one or more lighting assembly of the present invention as described above. Microwave ovens in accordance with this aspect of the present invention will generally have a cooking chamber defined by a top wall, a bottom wall, three side walls and a door; and one or more lighting assembly as described above. The lighting assemblies are each positioned behind an aperture disposed on the top wall allowing light to be projected therethrough into to the cooking chamber.

In a preferred embodiment, the microwave oven has two light assemblies each configured to project a spot light. The light assemblies are positioned on the opposite ends of the top wall and angled towards the center of the cooking chamber such that the spot lights from each of the two lighting assemblies substantially overlap so as to substantially eliminate shadows casted by each other when an object is placed in the region illuminated by the spot lights.

Yet another aspect of the present invention is directed to a method of forming a microwave oven with improved illumination for its cooking chamber. Microwave ovens formed by methods of the present invention will generally have a cooking chamber defined by a top wall, a bottom wall, three side walls and a door. Methods in accordance with this aspect of the invention will generally include the steps of placing a lighting assemblies behind an aperture disposed on one of the walls of the microwave oven's cooking chamber. The lighting assemblies used are as described above. In a preferred embodiment, the method further includes a step of angling the lighting assembly towards the center of the bottom wall. In another preferred embodiment, the method further includes a step of forming two apertures positioned on the opposite ends of the top wall; and place a light assembly as described above behind each of the aperture. In still another preferred embodiment, the method further include a step of configuring the light assembly to cast a spot light towards the center of the cooking chamber.

One advantage of the present invention is that because the lamp is included in the lighting assembly, and the lighting assembly is placed outside of the microwave oven cavity, the lamp is prevented from being exposed to microwaves which obviates the need for a protective metal mesh as required in prior art devices. At the same time, the light can be directed from the lamp into the cooking chamber in any desired angles without structural hindrance. Such a lighting assembly is also referred to herein as a “focalizer” and the light-guiding members as “lenses”.

The focalizer form a stand-alone optical design capable of accommodating any kind of lamp commonly known in the art, but is preferably coupled with a light emitting diode (LED) as the lighting source.

The focalizer can have any desired number of lenses. Two lenses, one for light collecting and the other for light condensing and distributing, have proven to be advantageous, however. The lens for light collecting is referred to hereinafter as a “collector lens” and the lens for light condensing and distributing as “a condenser lens”.

In particular embodiments of the invention, the collector lens may be a total internal reflection (TIR) lens and the condenser lens may be cone-shaped with a flat-top tip. The two lenses are placed in tandem so the light is collected by the TIR lens and conveyed to the condenser lens and then distributed through the flat-top surface. The flat-top surface of the condenser lens may be advantageously concave, to better distribute the light.

In other particular embodiments of the invention, the collector lens and the condenser lens can be molded into one integral piece in order to minimize the light loss during the conveyance from one lens to another.

The focalizer can illuminate the microwave oven cavity from any location of the oven walls. An overhead installation of the focalizer right above the microwave door is most advantageous, however. The focalizer can be tilted towards the center of the cavity floor. Any desirable number of focalizers can be adopted for a microwave oven but two focalizers are found to be advantageous.

Other aspects and advantages of the invention will be apparent from the following description and the appended claims.

### BRIEF DESCRIPTION OF THE DRAWINGS

FIG. 1 shows a prior art microwave equipped with a conventional incandescent lamp located in the cavity behind a protective metal mesh.

FIG. 2 shows a schematic view of one embodiment of the lighting assembly.

FIG. 3 A-B show the back view, and the front view, respectively, of one embodiment of the lighting assembly.

FIG. 4 shows light paths and range of illuminating angle emanating from one embodiment of the lighting assembly.

FIG. 5 shows a schematic view of a second embodiment of the lighting assembly.

FIG. 6 shows an exemplary positioning configuration of one embodiment of the lighting assembly in a microwave oven cooking chamber.

FIG. 7 shows a front perspective view of the positioning configuration of one embodiment of the lighting assembly in a microwave oven cooking chamber.

FIG. 8 shows the enlarged positioning configuration of the embodiment of the lighting assembly in the microwave oven cooking chamber.

FIG. 9 illustrates an exemplary illumination pattern in the positioning configuration of one embodiment of the lighting assembly in a microwave oven cooking chamber.

### DETAILED DESCRIPTION

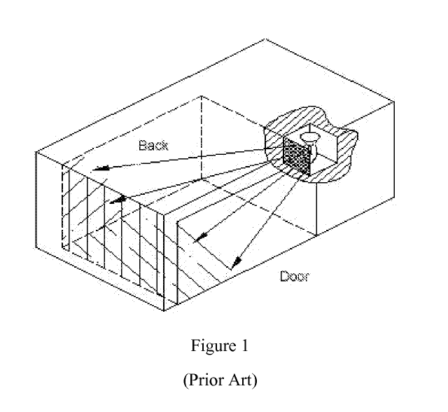

FIG. 1 shows an example of a prior art lighting devices for microwave ovens. The device is a typically small, tungsten filament appliance light bulb (about 25 watts) which radiates about 200 lumens. The life expectancy of such light bulbs are normally around 200 hours. However, these light bulbs are vulnerable to microwaves because microwave energy is capable of heating the tungsten filament to destructive levels. For example, in a typical 25 watt light bulb operating on 120 volts AC, it will draw about 0.2 amperes. But when the light bulb's filament is exposed to microwaves, additional current may be induced, which can push the total current flowing through the filament to exceed its rated value, causing the filament to quickly burn out. This problem is made worse if the bulb is used in one of the newer combination microwave/convection ovens in which the temperature within the oven can rise to as high as 400° F. At this temperature, the heating effects of the microwave in addition to the heating effects of the AC current supply can quickly raise the filament temperature above its rated value.

As illustrated in FIG. 1, to address this problem prior art microwaves hide the appliance light bulb in a small cavity formed in one of the walls of the cooking chamber and cover it with a screen to prevent microwave energy from reaching the bulb filament. Unfortunately, such a placement of the bulb causes a severe reduction in the amount of illumination reaching the cooking chamber. For example, only a small fraction of the generated light from the bulb will actually reach the screen. The protective shield will further cut the amount of transmitted light to about half of the light that falls on the screen. As a result, only about four percent of the light generated from the light bulb actually reaches the oven cavity. Much of this remaining light is lost in the cavity via absorption by the oven walls and oven contents so that the result is a very dimly lit cavity. To make the matter worse, viewing windows provided on the access doors for microwave ovens also are equipped with microwave-impervious screens, which further reduce the amount of the light that can pass through the window for viewing. The end result is that in a typical prior art oven employing a 25 watt light bulb, only less than 0.3 foot-candles of light will actually exit the oven through the oven window. This level of light is far below the minimum required for a user to accurately discern forms and colors.

To achieve good color rendition, a light source should produce a spectral continuum with visual intensities of about 10 candle power. Although high temperature incandescent light bulbs are capable of producing this level under normal conditions, when light intensity is low, true colors cannot be detected by human eyes. In particular, when the light intensity is below 10 foot-candles of light, human vision becomes unable to detect true colors. At about 0.5 foot-candles, human vision is essentially color blind.

U.S. Pat. No. 5,712,468 issued to Ace (1998) discloses a system that uses quartz halogen lamps located at the front of the oven or near the top instead of in a separate chamber. It also proposes using lamps with shorter and thicker filaments that can withstand exposure to microwave or filament-less lamps such as point-source gas discharge or arc lamps. However, halogen lamps must operate at higher temperatures which makes their quartz envelope vulnerable to oils and other contaminants. For example, oil from human fingertips or food can create a hot spot on the bulb surface when the bulb is turned on. The localized hot spot will cause the quartz to change from its vitreous form into a weaker crystalline form that leaks gas. To avoid contamination, additional protected shields must be used, which in turn reduces the efficacy of the lamps' illuminating power, rendering the device more complex and expensive to manufacture. Moreover, in order to achieve adequate lighting, the power required to drive the halogen lamp and the associated transformer are substantial, which reduces the amount of power available for cooking

The known microwave oven lighting devices are not capable of providing sufficient light because of protective yet intrusive structures for the light bulbs, as well as their low lighting efficiency. As noted above, it remained for the present invention to recognize the need to make microwave oven lighting devices more powerful without the increasing expense of extra electricity usage and whose manufacture provides numerous benefits, as detailed hereinabove. Indeed, the incandescent light bulb in FIG. 1 consumes 20 watts and radiates only 200 lumens and of that amount, only a remnant (4%) reaches the oven cavity.

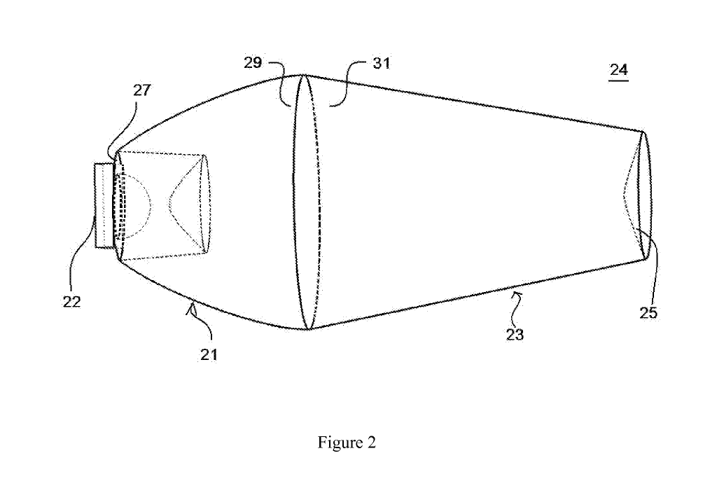

### FIG. 2-4—A First Preferred Embodiment

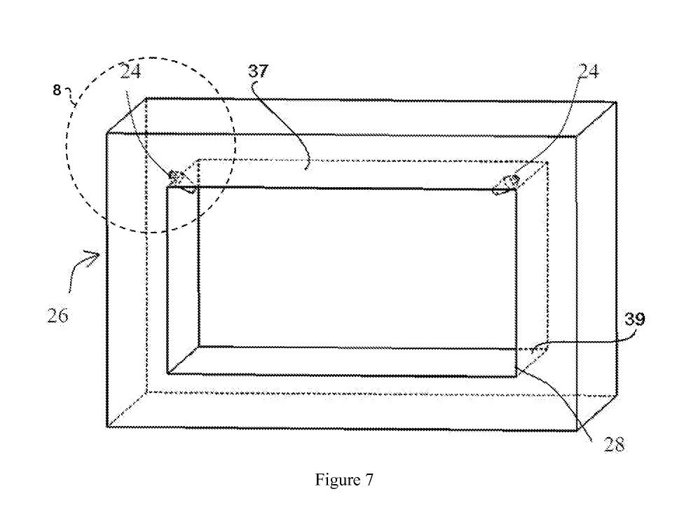

FIG. 2 depicts an exemplary lighting assembly, or “focalizer,” 24. FIG. 7 illustrates the usage of said focalizer, embodying the principles of the present invention that provide a light source of high-illumination and low energy-consumption, and a high-efficiency light-delivering system for conveying the light into the microwave oven cavity via an aperture on the wall. Our assembly brings much more light into the oven cavity compare to those of prior art lighting assemblies and is easy to manufacture. It essentially prevents the lamp from being exposed to microwaves and obviates the need for a protective metal mesh.

As shown in FIG. 2, the focalizer 24 comprises an LED 22, a light-collecting lens (or collector lens) 21, and a light-distributing lens (or condenser lens) 23. The collector lens 21 and the condenser lens 23 form a lamp-front assembly. The focalizer 24 has a generally streamlined shape like a fish where the LED 22 is the mouth, the collector lens 21 the rest of the head, and the condenser lens 23 the body. The three parts are connected in tandem closely.

In this embodiment, the LED 22 is a lamp with 100 lumens output and operational at 3.2-3.6V, 350 mA, 1W. Most of the LED 22 body is enveloped by the collector lens 21 for maximal light collection but the basal part of the LED 22 is exposed outside for heat dissipation.

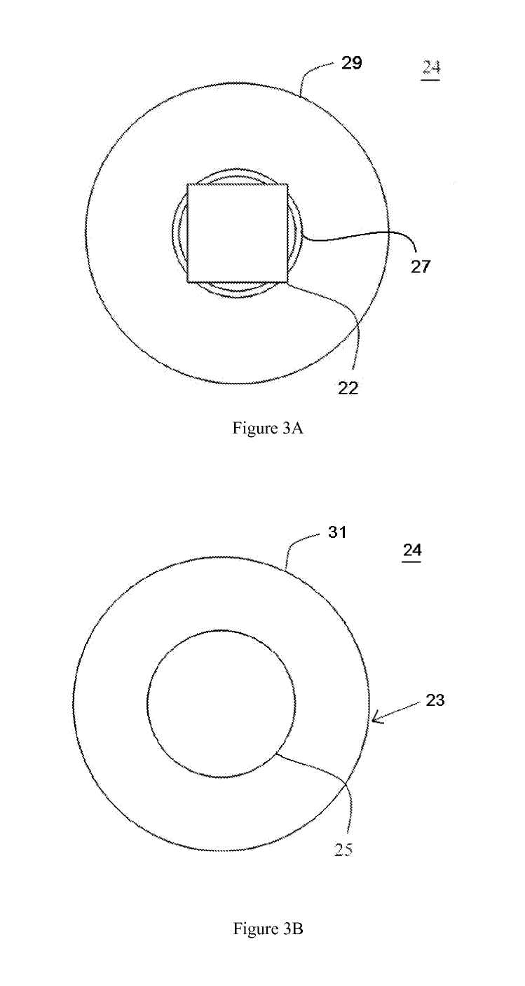

The collector lens 21 is a bowl-shaped lens and has a base 27 and a distant end 29 with bigger diameter. The distant end 29 has a round flat surface. The collector lens base 27 is a light-receiving end, configured to accommodate and attach the LED 22. The LED 22 is simply clipped onto the base 27 without the need for extra materials. The bulb of the LED 22 is entirely enveloped by the collector lens 21. In this way the light leakage from the assembly is minimized. Viewed from outside, only the rear end of the LED 22 is exposed for heat dissipation, as shown in FIG. 3A.

The surrounding side surface of the collector lens 21 has a property of total internal reflection (TIR), and the collector lens 21 is a total internal reflection (TIR) lens. The collector lens 21 can reduce light from escaping and direct the received light with an efficiency of over 96%. One of skill in the art would recognize that a TIR lens may be constructed using the techniques currently used in optics design.

The condenser lens 23 is a cone-shaped lens but the tip of the cone is cut. The condenser lens 23 comprises a base 31 and a discharging end 25. The base 31 has a round flat surface with the same area with the distal end 29 of the collection lens 21, which enables the base 31 to exactly match with the distal end 29 of the collection lens 21. In this way the condenser lens 23 is seamlessly coupled (or integrated) with the distal end 29 of the collection lens 21.

The discharging end 25 is a light-exiting end for distributing the light into the microwave oven cavity. To protect the LED 22 from microwaves, the discharging end 25 has a substantially small surface (only one quarter of the plane area of the base 31), as shown in FIG. 3B. The small surface of the discharging end 25 greatly decreases the microwave leakage. Additionally, the surface of the discharging end 25 is a round concave surface, in order for the light to be fanned out maximally.

In this embodiment, the collector lens 21 and the condenser lens 23 are made of Poly(methyl methacrylate) (PMMA), a transparent thermoplastic. The lenses are single-piece constructions molded, cast, or machined from PMMA. With the disclosure, one of skill in the art would construct the lenses using the techniques currently used in the art.

The three parts of the focalizer 24, e.g. the LED 22, the collector lens 21 and the condenser lens 23, are bonded together tightly. Since the collector lens base 27 is configured to attach to the LED 22, the LED 22 simply clips on to the collector lens 21. The collector lens distant end 29 and the condenser lens base 31 can be permanently glued together. There is nothing substantial in the interface of the two lenses 21 and 23.

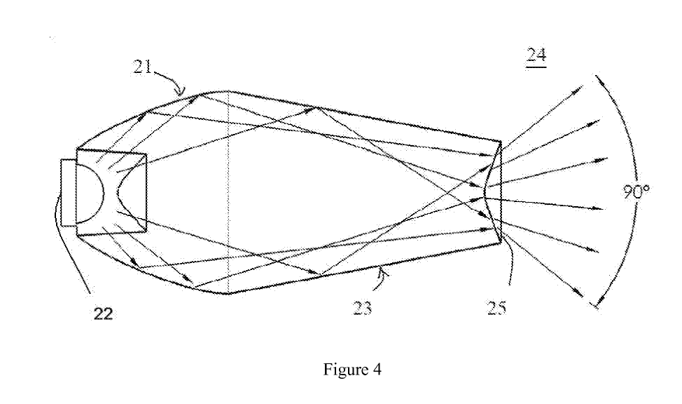

FIG. 4 shows the light path of the focalizer 24 in this embodiment. As the light rays emanate from the LED 22 and enter the collector lens 21 through the base 27, the surrounding side surface of collector lens 21 takes advantage of its TIR properties to collect the light rays. After that, the light rays are reflected towards the distant end 29 and enter the condenser lens 23 through the base 31. The light rays are condensed to some degree in the distribution lens 23 before passing through the discharging end 25. Lastly the light rays enter the microwave cavity and are distributed at an approximate angle of 90°.

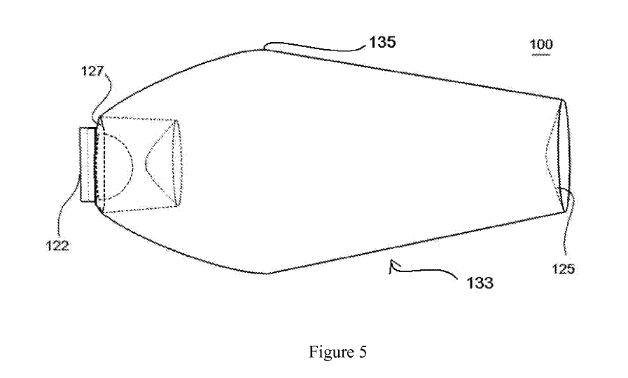

### FIG. 5—A Second Preferred Embodiment

In a second exemplary embodiment of the lighting assembly, the focalizer has one integral lens in order to minimize any loss during the light relaying process, as well as to make simpler the manufacture of the lighting assembly.

FIG. 5 shows a schematics illustration of a focalizer 100 according to the second embodiment of the lighting assembly. The focalizer 100 differs from the focalizer 24 in the first embodiment in that the lens is molded in one piece and functions as a combination of the collector lens 21 and the condenser lens 23 of the first preferred embodiment. Specifically, the focalizer 100 comprises a LED 122 and a lens 133. The LED 122 is a lamp with 100 lumens output and operational at 3.2-3.6V, 350 mA, 1W. Most of the body of LED 122 is enveloped by the lens 133 for maximal light collection but the basal part of the LED 122 is exposed for heat dissipation

The lens 133 is a stand-alone lamp-front assembly and spindle-shaped. It has a base 127 and a discharging end 125, with a bulging section 135 in the middle. The portion from the base 127 to the bulging section 135 is gradually bulging out for collecting the light, identical to the collector lens 21 in the focalizer 24. The portion from the bulging section 135 to the discharging end 125 is tapering for condensing and distributing the light, identical to the condenser lens 23 in the focalizer 24.

Identical to the base 27 in the focalizer 24, the base 127 is a light-receiving end, configured to accommodate and attach the LED 122 so that the bulb of the LED 122 is entirely enveloped by the lens 133. The LED 122 is simply clipped onto the base 127 without the need for extra materials. In this way the light leakage from the assembly is minimized. Viewed from the outside, only the rear end of the LED 122 is exposed for heat dissipation.

For the part from the base 127 to the bulging section 135, the surrounding side surface has a property of total internal reflection (TIR), identical to the collector lens 21. One of skill in the art would recognize that such a feature as TIR may be constructed into the lens using the techniques currently used in the art.

For the part from the bulging section 135 to the discharging end 125, the lens is tapered, i.e. gradually becoming narrower. Identical to the discharging end 25 in the focalizer 24, the discharging end 125 is a light-exiting end for distributing the light into the microwave oven cavity, and has a relatively small surface area (approximately one quarter of the plane area of the bulging section 135). The small surface area of the discharging end 25 advantageously decreases the microwave leakage around it. Identical to the discharging end 25 in the focalizer 24, the surface of the discharging end 125 is a round concave surface, in order for the light to be maximally fanned out.

Identical to the collector lens 21 and the condenser lens 23 in the focalizer 24, the lens 133 is made of PMMA. The lens can be molded, cast, or machined from a single-piece construction of PMMA. With the disclosure, one of skill in the art would construct the lenses using the techniques currently used in the art.

The light path of the focalizer 100 (omitted in the drawings) is identical to that of the focalizer 24. As the light rays emanate from the LED 122 and enter the lens 121 through the base 127, the surrounding side surface of collector lens 121 acts with TIR properties and is able to collect the light rays. After that, the light rays are reflected towards the discharging end 125. The light rays are condensed to some degree in the lens 133 as the lens 133 gradually tapers before passing through the discharging end 125. Lastly the light rays enter the microwave cavity and are distributed at an approximate angle of 90°.

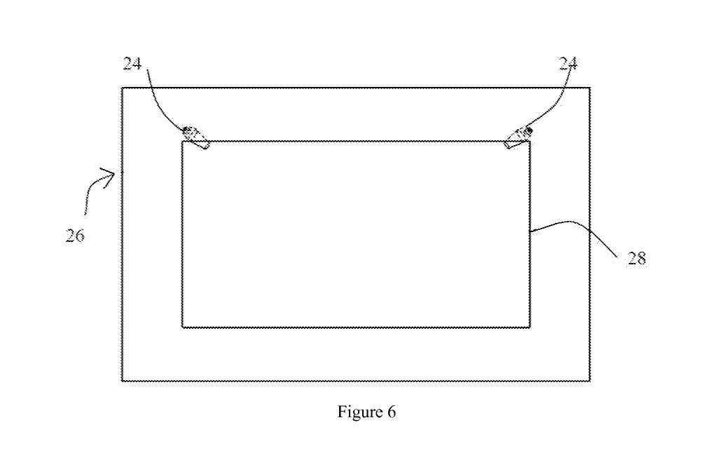

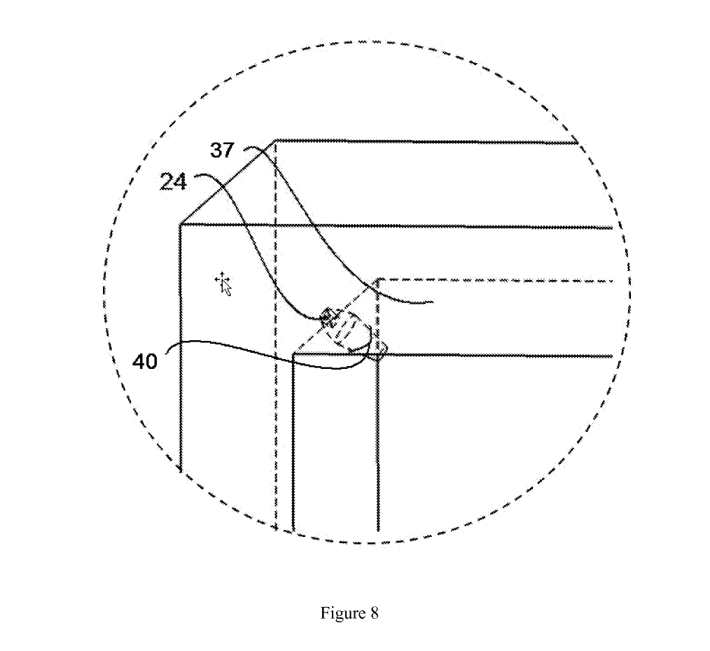

### FIG. 6-8—Operation

The positioning configuration and the illumination pattern of conventional incandescent bulbs in the microwave oven cavity are shown in FIG. 1. The conventional incandescent bulb used in the microwave oven is placed inside the side walls, covering by a metal mesh, so the illuminating angle is limited and the brightness is largely reduced. Due to the position of the light bulb, the illuminated area is limited in area and typically does not cover the whole oven.

A cooking chamber (or microwave oven cavity) typically has a top wall, a bottom wall, three side walls and a door. In preferred embodiments, the focalizer is connected with electrical wires (omitted in the drawings), put behind the side wall of the microwave oven, and shoots light beams into the cooking chamber through a small hole (or an aperture) in the oven. FIGS. 6-8 show one embodiment of the invention, which has two focalizers 24, located within a microwave oven 26. The microwave oven 26 has a door 28, a top wall 37, and a bottom wall 39. The top wall 37 has an aperture 40, behind which the focalizer 24 is installed. For this particular embodiment, the discharging end of the focalizer 24 is in the cooking chamber; the LED is behind the aperture 40; the body is fixed to the aperture 40 with permanent glue. The focalizers 24 are close to and overhead of the microwave door 28, directing the light towards the center of the bottom wall (or the oven cavity floor) 39.

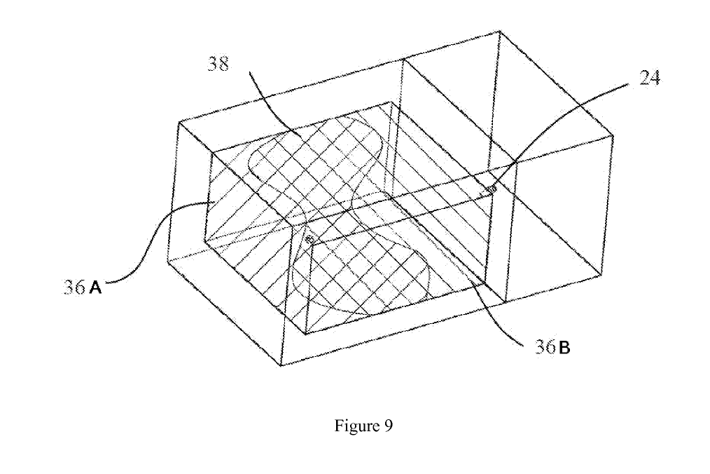

As shown in FIGS. 6-8, the light can be directed from the focalizers 24 into the microwave oven cavity in any desired angles without structural hindrance. The illumination pattern of this embodiment is shown in FIG. 9. The lightened area of the microwave cavity walls are roughly divided into three partitions: a first bright area 36A, a second bright area 36B, and an enhanced bright area 38. The light rays emitted from two focalizers 24 are illuminating the target walls, each of them bringing brightness to the first bright area 36A or to the second bright area 36B. In the middle part of the oven cavity, however, the light rays overlap and then produce the enhanced bright area 38, resulting in higher brightness. The light angle of this invention can be adjusted according to the size of the oven, thereby solving the problem of the single angle and small emitting angle of lighting systems in conventional microwave ovens.

There are two main benefits of this design. First, it is easy to control illumination angles and light paths so that more light can reach desired areas, which results in high light energy utilization and an even illuminating effect, Second, light transmission is completed effectively in this way. Therefore, preferred embodiments can provide a method to illuminate regions where adequate lighting is difficult to achieve with conventional incandescent lamps due to constraints of the intended environment.

A microwave with conventional incandescent bulbs as in FIG. 1 may also be retrofitted with the lighting assemblies of this invention, positioning them at the two top corners near the access door. The two lights are placed in a crossfire pattern, emitting light to the center of the cavity floor (or the bottom wall).

### Other Exemplary Embodiments

In one or more embodiments according to the invention, other LED lamps are used, which have different output and are operational at certain voltages. Also used are other kinds of lamps or combination of other lamps, such as tungsten halogen lamps, xenon short arc lamps, metal halide lamps and derivatives of these technologies. These other lamp types can be used because the lighting devices of the present invention more efficiently provide light to the microwave oven cavity. Additionally, in one or more embodiments the base around the lamp (such as the bases 27 or 127 in the preferred embodiments) is enlarged and a plurality of lamps can be attached to the light-collecting lens.

In one or more embodiments according to the invention, the focalizer has three or more lenses. The lenses are seamlessly attached with each other (or integrated) and work collectively for initial light-collecting and then light-condensing before casting the light into the microwave oven cavity. The lenses are bonded together with glue or using some means for physical binding.

In one or more embodiments according to the invention, metallic reflectors are used for light-collecting and light-condensing, or in combination with the TIR or the condenser lenses in the preferred embodiments.

In other embodiments in accordance with the invention, the material of the lenses is glass, polycarbonate, polystyrene, or some other kind of acrylic. The material should have high transmittance characteristics. The lenses are molded, cast, or machined in any desired way.

In other particular embodiments in accordance of the invention, the surface of the discharging end (such as the discharging ends 25 or 125 in the preferred embodiments) is formed so that the light rays enter the microwave cavity and are distributed at an angle of any desired degree.

In one or more embodiments according to the invention, other focalizers are used, such as the focalizer 100.

In one or more embodiments according to the invention, two focalizers are installed behind the walls as in the embodiment shown in FIG. 7 but installed on the opposite positions of each other with the center of the oven cavity in the middle. The two focalizers are facing each other and the center of the cavity is the common focus of them so that the food placed on the cavity floor can be brightly illuminated and the shadows are eliminated.

In one or more embodiments according to the invention, only one focalizer is used to illuminate the microwave oven cavity. The focalizer is placed in the middle of the space right above the cavity door. In other embodiments, more than two focalizers are used to illuminate the oven cavity. They are installed behind the surrounding walls and illuminate the cavity from multiple angles. The installation pattern can be modern and stylish.

Each of these details provides particular advantages and can be implemented independently of the others.

### Advantages

The description above makes evident a number of main advantages of our high-efficiency low-energy-consumption lighting device for illuminating the microwave oven cavity:

(a) The use of single-piece lenses makes the structure simple, the illuminating efficiency high, and the lighting pattern design adjustable, all of which can better light the microwave oven cavity and reduce the cost of the microwave oven manufacture.

(b) The use of the LED as the light source in the preferred embodiments, provides high and even brightness of light and various lighting angles; high light energy efficiency, and effective energy saving; easy installation; compact size, simple structure, applicable to lighting the microwave oven of different sizes; the embodiments not only enable the microwave oven to have a better lighting distribution, but also decreases the complexity of the lighting subsystem.

Although the present invention has been described in terms of specific exemplary embodiments and examples, it will be appreciated that the embodiments disclosed herein are for illustrative purposes only and various modifications and alterations might be made by those skilled in the art without departing from the spirit and scope of the invention as set forth in the following claims

What is claimed is:

1. A lighting assembly for use in a microwave oven, comprising:
a lamp for generating light; and
a lamp-front assembly comprising one or more light-guiding members integrated for collecting, condensing and distributing light generated by the lamp, said lamp-front assembly having:
a light-receiving end,
a light-exiting end, and
a bulging section connecting the light-receiving end and the light-exiting-end;
wherein the lamp is embedded in the light-receiving end of said lamp-front assembly, the portion of said lamp-front assembly from the light-receiving end to the bulging section is configured for light collection, and the portion of said lamp-front assembly from the bulging section to the light-exiting end tapers for light condensing and distributing into the microwave oven.

2. The lighting assembly of claim 1, wherein said lamp is a light emitting diode (LED).

3. The lighting assembly of claim 1, wherein said light-guiding member(s) are single-piece lenses.

4. The lighting assembly of claim 3, wherein at least one of the single-piece lenses is a total internal reflection (TIR) lens.

5. The lighting assembly of claim 1, wherein said light-exiting end of said lamp-front assembly has a concaved shape.

6. The lighting assembly of claim 1, wherein said lamp-front assembly comprises a first lens forming the portion of said lamp-front assembly from the light-receiving end to the bulging section for light collection, and a second lens forming the portion of said lamp-front assembly from the bulging section to the light-exiting end, the second lens having a tapered shaped for light condensing and distributing, the lenses being seamlessly connected to each other at the bulging section.

7. A lighting assembly for use in a microwave oven, comprising:
a LED lamp for generating light; and
a single-piece TIR lens placed before the LED lamp for collecting, condensing and distributing the light, wherein the single-piece TIR lens has
a light-receiving end,
a light-exiting end, and
a bulging section in the middle;
wherein the LED lamp is embedded in the light-receiving end of the single-piece TIR lens, the light-exiting end of the single-piece TIR lens is concave, the portion of the single-piece TIR lens from the light-receiving end to the bulging section is configured for light collection, and the portion of the single-piece TIR lens from the bulging section to the light-exiting end tapers for light condensing and distributing into the microwave oven.

8. A microwave oven, comprising:
a cooking chamber defined by a top wall, a bottom wall, three side walls and a door; and
one or more lighting assembly of claim 1, wherein each of the one or more lighting assembly is positioned behind an aperture disposed on the top wall allowing light to be projected therethrough into the cooking chamber.

9. The microwave oven of claim 8, comprising the cooking chamber and two lighting assemblies, wherein each of the light assemblies is configured to project a spot light, and wherein the light assemblies are positioned on the opposite ends of the top wall and angled towards the center of the cooking chamber such that the spot lights from each of the two lighting assemblies substantially overlap so as to substantially eliminate shadows casted by each other when an object is placed in the region illuminated by the spot lights.

10. A method of forming a microwave oven with improving illumination for its cooking chamber, wherein said cooking chamber is defined by a top wall, a bottom wall, three side walls and a door, said method comprising:
placing a lighting assembly behind an aperture disposed on one of the walls of the microwave oven's cooking chamber, said lighting assembly comprising:
a lamp for generating light; and
a lamp-front assembly comprising one or more light-guiding members integrated for collecting, condensing and distributing the light, wherein the lamp-front assembly has
a light-receiving end,
a light-exiting end, and
a bulging section in the middle;
wherein the lamp is embedded in the light-receiving end of said lamp-front assembly, the portion of said lamp-front assembly from the light-receiving end to the bulging section is configured for light collection, and the portion of said lamp-front assembly from the bulging section to the light-exiting end tapers for light condensing and distributing into the microwave oven.

11. The method of claim 10, further comprising:
angling the lighting assembly towards the center of the bottom wall.

12. The method of claim 10, further comprises:
forming two apertures located on the opposite ends of said top wall; and
placing a lighting assembly of claim 1 behind each of the apertures.

13. The method of claim 11, further comprising the step of configuring said lighting assembly to cast a spot light towards the center of the cooking chamber.
